(19) United States
(12) Patent Application Publication
(10) Pub. No.: US 2008/0163984 A1
(43) Pub. Date: Jul. 10, 2008

(54) Blind or Awning Photo-Generator

(76) Inventor: Jacques Lambey, Lyon (FR)

Correspondence Address: HUGHES HUBBARD & REED LLP, ONE BATTERY PARK PLAZA, NEW YORK, NY, 10004, US

(21) Appl. No.: 11/813,317

(22) PCT Filed: Dec. 19, 2005
(86) PCT No.: PCT/IB2005/003812

§ 371 Date: Jul. 3, 2007

(30) Foreign Application Priority Data
Jan. 4, 2005 (FR) 0500028
Jan. 4, 2005 (FR) 0500029
Jan. 7, 2005 (FR) 0507005
Jul. 19, 2005 (FR) 0507637

(51) Int. Cl. E05F 15/20; E06B 9/42; H01L 31/045; E04F 10/06

(52) U.S. Cl. 160/2; 160/127; 136/246; 160/66

(57) ABSTRACT

The invention relates to a blind or awning photo-generator comprising first and second elements (1, 2) which are embodied in the form of a flexible cloth or an arrangement of bars (28) and movable between the folded and unfolded positions. The first element (1) is superimposed in a parallel position on the second element (2) at a certain distance when they are unfolded. Photovoltaic cells (6, 15, 20, 35, 37) are arranged on one and/or another element (1, 2) in such a way that the active photovoltaic surface of said cells (6, 15, 20, 35, 37) is located on the top and/or lower surface of the first element (1) and/or the top surface of the second element (2). The first element (1) allows sun light to pass at least partially when said two elements are arranged in such a way that the light is directed to the active photovoltaic surface of the cells (6, 15, 20, 35, 37) located on the lower surface of the first element (1) and/or on the top surface of the second element (2).

The present invention relates to the photovoltaic field, more particularly to a photo-generator blind or awning comprising photovoltaic cells in order to provide not only a usual solar protection inherent in blinds or awnings but also the production of electricity.

The incorporation of cloths or sheets of photovoltaic cells into blinds used amongst other things for patios or balconies is already part of the prior art. Publication WO 02/084044 describes a blind comprising, on the one hand, a cloth in which are encapsulated, in a succession of rows, preferably rigid photovoltaic cells and, on the other hand, a polygonal tube onto which said cloth can be rolled. The spacing between two adjacent rows of cells makes it possible to keep the latter on a plane parallel to one of the sides of the polygon defining the tube.

Publication WO 99/61721, for its part, discloses a similar device comprising a cloth on which flexible photovoltaic cells are placed, said cloth being able to be rolled onto a cylindrical tube.

The solar cells used by these devices have the disadvantage of having a relatively low output/cost ratio.

The object of the present invention is to propose a blind or awning comprising a first cloth superposed on a second cloth, the configuration of these cloths making it possible to substantially increase the electric output of the blind while limiting the considerable cost arising from the photovoltaic cells.

According to the invention, this object is achieved thanks to a photo-generator blind or awning as claimed in claim 1. This blind or awning comprises a first and a second element in the form of a flexible cloth or a set of bars. These two elements can move between a retracted position and a deployed position, the first element being superposed generally parallel on the second element at a certain distance when the latter are deployed. Photovoltaic cells are arranged on one and/or other of these elements, the active photovoltaic surface of said cells being situated on the upper surface and/or lower surface of the first element and/or on the upper surface of the second element. The first element allows the sunlight to pass through at least in part when the two elements are deployed. These elements are arranged so that the light is directed onto the active photovoltaic surface of the cells situated on the lower surface of the first element and/or on the upper surface of the second element.

The features of the invention will appear more clearly on reading a description of several embodiments given solely as an in no way limiting example with reference to the schematic figures, in which:

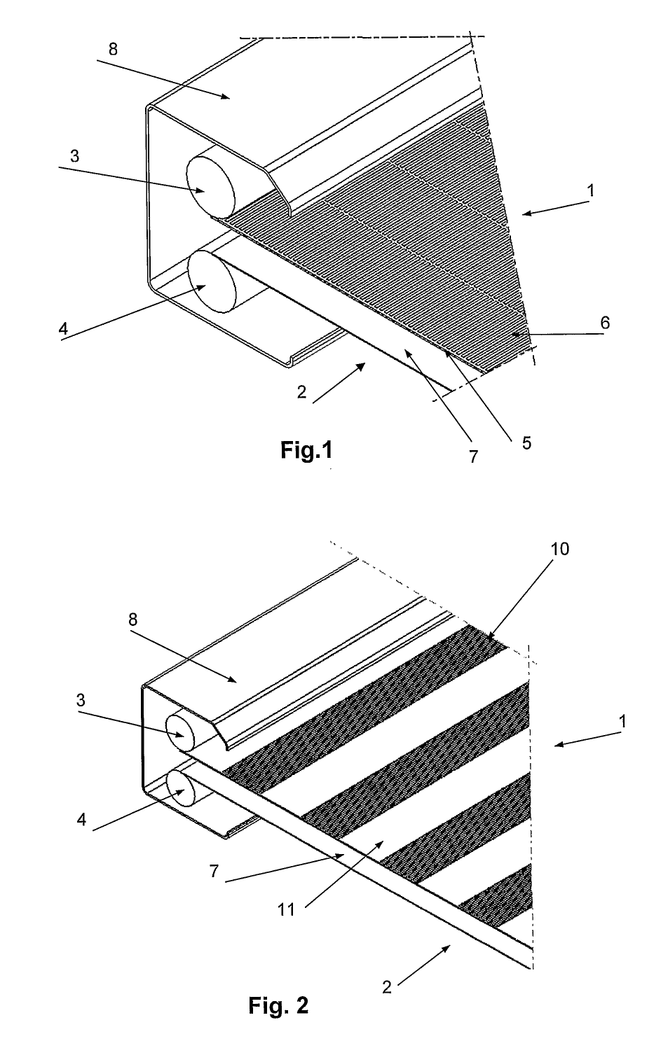

FIG. 1 represents a partial view in perspective of a blind or awning comprising a first element superposed on a second element according to a first embodiment of the present invention.

FIG. 2 represents a partial view in perspective of the blind or awning according to a second embodiment.

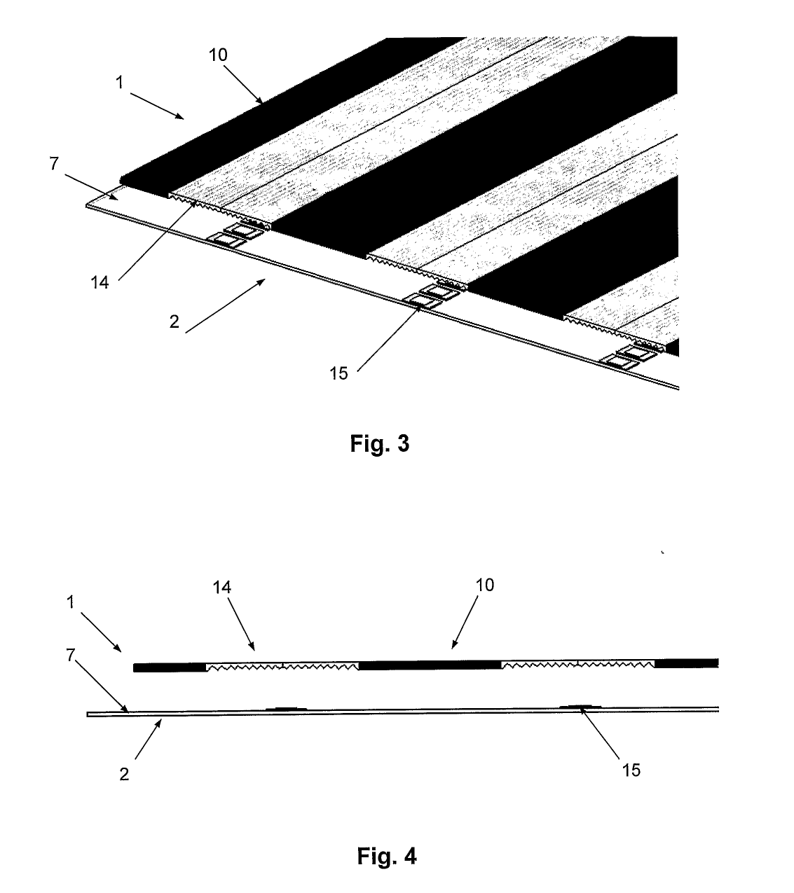

FIG. 3 represents a partial view in perspective of the blind or awning according to a third embodiment.

FIG. 4 represents a partial side view of FIG. 3.

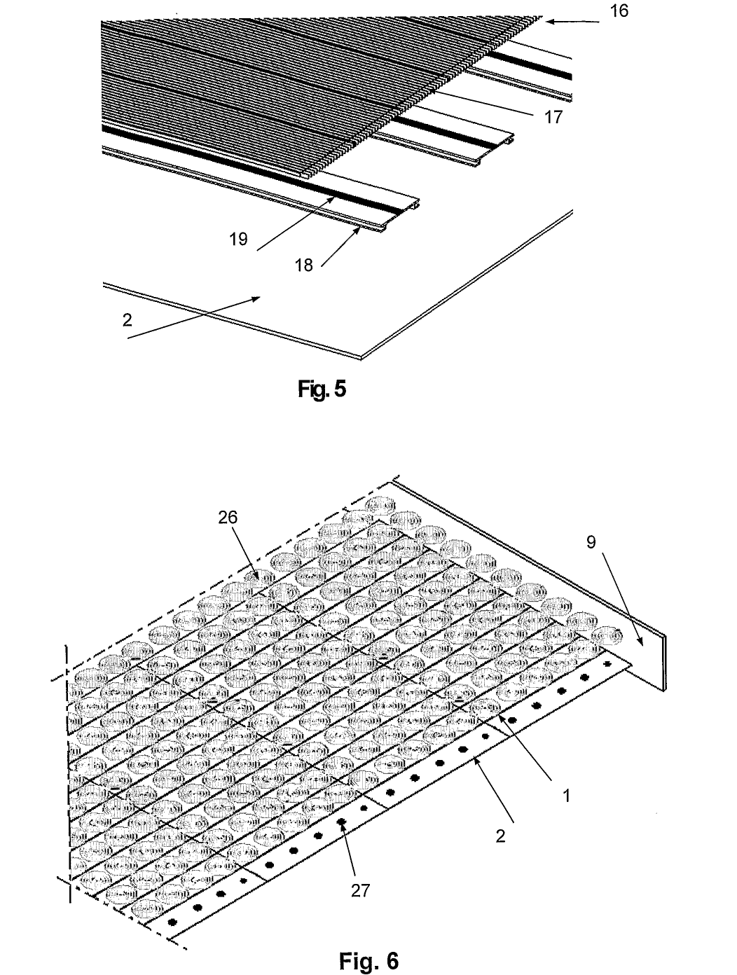

FIG. 5 represents a partial view in perspective of the blind or awning according to a fourth embodiment of the present invention.

FIG. 6 represents a partial view in perspective of the blind or awning according to a fifth embodiment.

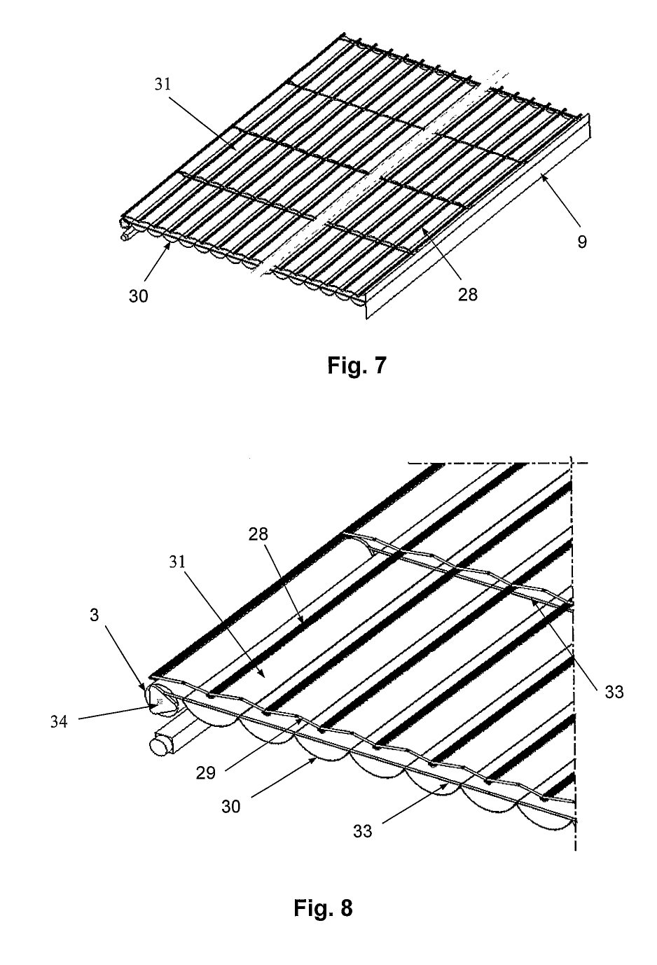

FIG. 7 represents a partial view in perspective of the top of the blind according to a sixth embodiment.

FIG. 8 represents a partial view in perspective of FIG. 7.

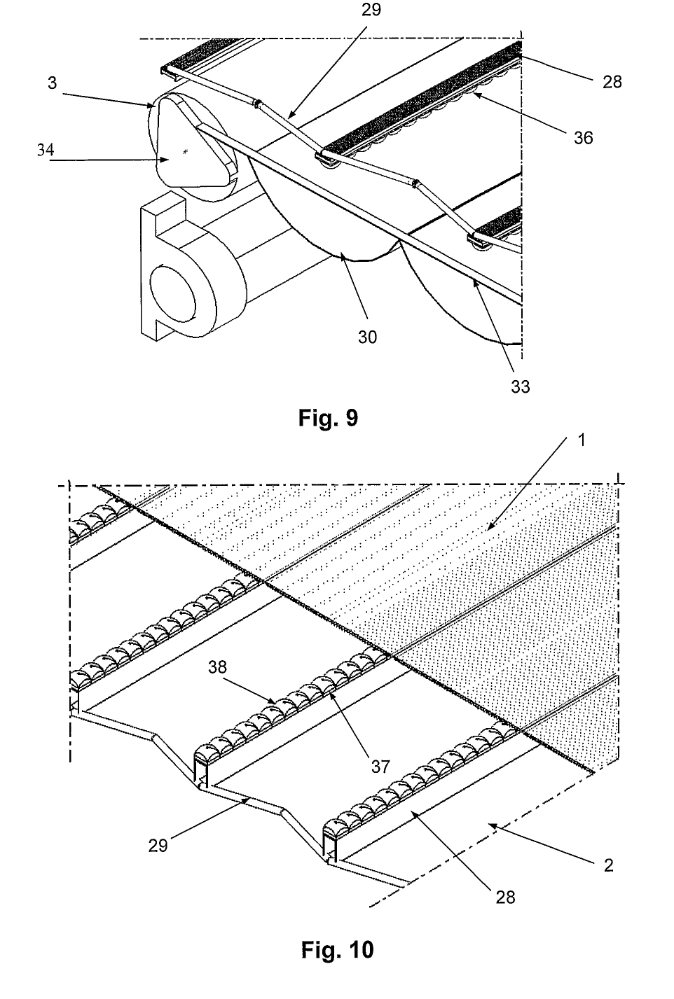

FIG. 9 represents a detailed view of FIG. 8.

FIG. 10 represents a partial view in perspective of the blind or awning according to a seventh embodiment.

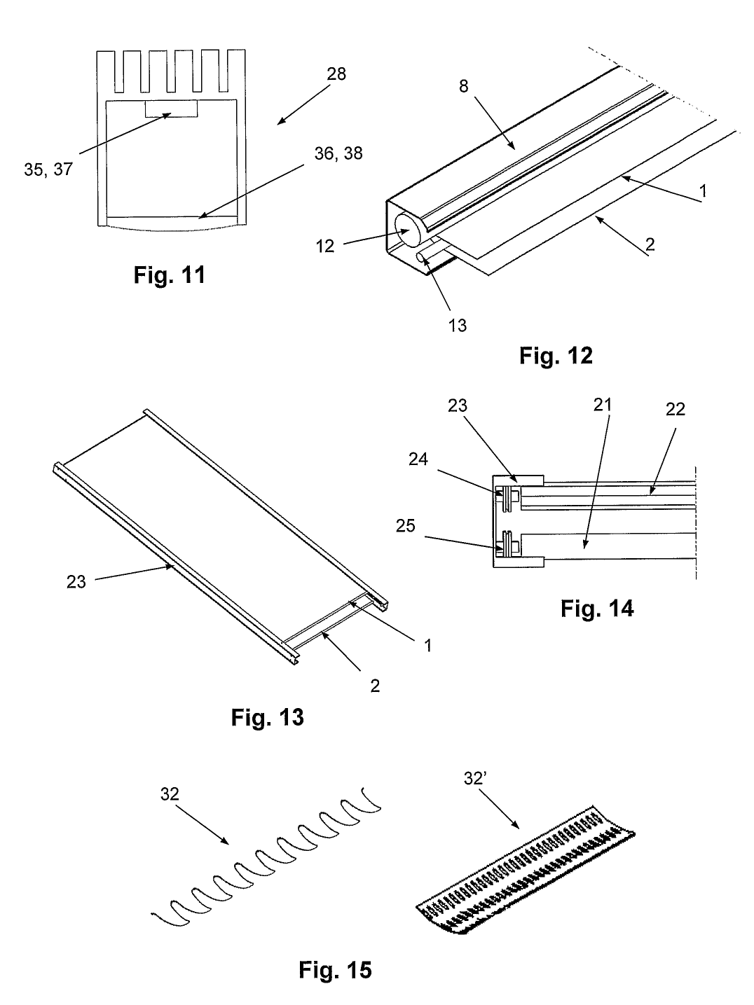

FIG. 11 represents a cross section of a bar comprising a Fresnel lens and a photovoltaic cell according to the sixth or seventh embodiment.

FIG. 12 represents a partial view in perspective of a support according to a variant of the rolling of one of the aforementioned embodiments.

FIG. 13 represents a view in perspective of the awning comprising two slides.

FIG. 14 represents a partial front view of FIG. 13.

FIG. 15 represents respectively a curved strip and a perforated strip.

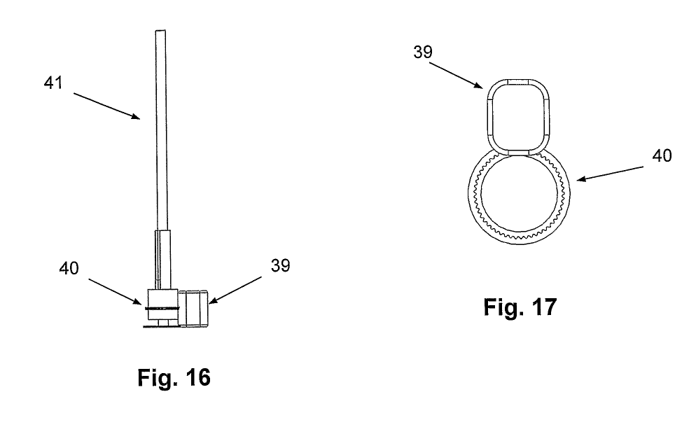

FIG. 16 represents a front view of a reduction gear and an axial support comprising a crown wheel.

FIG. 17 represents a view in cross section of the reduction gear and the axial support.

According to a first embodiment of the present invention (FIG. 1), the first and the second element (1, 2) of the blind or awning are respectively a first cloth (1) called upper and a second cloth (2) called lower. The first cloth (1) is superposed parallel on the second cloth (2), the latter being of substantially identical dimensions. These cloths (1, 2), that are separated from one another by a certain distance, are capable of being rolled onto two separate supports (3, 4). A transparent film (5), on the inside of which bifacial photovoltaic cells (6) are encapsulated in small strips available under the Sliver brand, forms the totality of the upper cloth (1). This film (5) is preferably made of polyvinylfluoride sold for example under the Tedlar®, brand. Other encapsulation films such as “ETFE” may be used. These films have optimal mechanical and optical properties (high coefficient of transmittance) for this type of application.

The second cloth (2) arranged beneath the first cloth (1) has on its lower face the same appearance as conventional blind cloths. It may for example be made of acrylic or cotton. On the other hand, its upper face is totally covered by a flexible reflector (7) made of laminated 12 μm metallized (Ag or Al) plastic film (for example made of PET). This reflector (7), on the one hand, receives a large proportion of the diffuse or direct solar rays that have passed through the surface corresponding to the spacing between each cell (6) of the upper cloth (1) and, on the other hand, redirects a portion of these rays onto the lower surface of the bifacial photovoltaic cells (6) encapsulated in the upper cloth (1).

There are various flexible modules made up of a transparent film as described above in which said cells (6) are encapsulated. The dimensions of the latter are of the order of 80 mm to 120 mm for the length and from 1 to 3 millimeters for the width. The spacing between each cell (6) is normally situated between 0.5 mm and 3 mm. This spacing determines the cost and output of the module. Several modules can be juxtaposed side by side so as to form the whole surface of the upper cloth (1).

The supports (3, 4) onto which the cloths (1, 2) can be rolled are cylindrical, elliptical or polygonal tubes. The upper cloth (1) formed of said modules and the lower cloth (2) comprising the reflector (7) have little thickness allowing said cloths (1, 2) to be integrated into a blind case (8) once the latter are totally rolled up onto the support (3, 4). One of the ends of the cloths (1, 2) is attached to the support (3, 4), the other of its ends preferably being attached to a lambrequin (9) (FIGS. 6 and 7). In order to ensure an optimal output of the bifacial photovoltaic cells (6), the distance between the upper cloth (1) and the lower cloth (2) is chosen to be between 10 mm and 100 mm.

According to a second embodiment of the present invention as illustrated by FIG. 2, the upper cloth (1) consists of several tapes (10) consisting of flexible bifacial thin films, 10 to 300 μm thick, comprising single-junction photovoltaic cells, for example made of mono and polycrystalline silicon or gallium arsenide (GaAs), or multiple-junction photovoltaic cells consisting of heterostructures such as the alloy “GaInP/GaAs/Ge”. Thin films of the “CIGS”, “CuInSe2” or “CdTe” type may also be used.

Given that all these thin films (10) are opaque, a band of transparent film (11) preferably made of polyvinylfluoride is arranged on either side of each strip (10) so that a large proportion of the diffuse and direct solar rays can reach the reflector (7). The latter redirects these rays onto the lower face of the photovoltaic cells inherent in the thin films (10) encapsulated in the upper cloth (1).

This set of two superposed cloths (1, 2) makes it possible to satisfy the weight, cost and radiation requirements. Irrespective of the sunshine of the region for which the blinds or awnings are intended, the surface of the flexible bifacial thin films (10) comprising the photovoltaic cells is divided into two. This surface is identical to the surface of the band of transparent film (11) that separates said films (10) and allows the lower face of the photovoltaic cells inherent in the thin films (10) to receive the solar radiation by means of the reflector (7).

According to a variant of the first two embodiments, the supports (3, 4) are replaced by a single and unique support consisting of a single tube (12) (FIG. 12) onto which the two cloths (1, 2) can be rolled. An additional rotary tube (13) is arranged close to the tube (12) in order to maintain a constant distance between the cloths (1, 2).

In a third embodiment of the present invention, each of the transparent bands (11) of the second embodiment is replaced by a series of Fresnel lenses (14) that are preferably linear (FIGS. 3 and 4).

It is a known practise to use Fresnel lenses in the aerospace field. For equal outputs, these lenses make it possible to divide the surface of the photovoltaic cells by 10 to 100 times. Document U.S. Pat. No. 6,111,190 describes such a device made up of expandable Fresnel lenses.

Each lens (14) concentrates the direct solar radiation onto a line of silicon or single-junction or multiple-junction photovoltaic cells (15) arranged on the reflector (7). In this embodiment, the lower face of the bifacial thin films (10) exposed to the reflector film (7) have the particular feature of also receiving the infrared radiation originating from the heating of the cells (15) subjected to the radiation concentrated by the Fresnel lenses (14). The direct solar radiation may be concentrated up to 2000 times on certain multiple-junction photovoltaic cells. However, it is preferable not to concentrate the direct solar radiation beyond 500 times in order to prevent problems resulting from the heating of these cells.

According to a fourth embodiment (FIG. 5), the upper cloth (1) consists of a flexible and transparent film (16) entirely formed of several rows of linear Fresnel lenses (17). A fine metal or plastic mesh (not illustrated) is bonded between the lenses (17) and the silicone film that covers them in order to ensure the flexibility of the film (16) while providing it with a constant rigidity. The lower cloth (2) comprises several strips (18) on which lines of photovoltaic cells (19) are placed, said strips (18) being arranged on the focal lines of the Fresnel lenses (17).

According to FIG. 12 or 14, the two cloths (1, 2) may be rolled separately or jointly respectively onto the tube (12) or onto two motorized tubes (21, 22) capable of actuating cables or belts (not illustrated) positioned in slides (23), which are arranged on either lateral side of the cloths (1, 2). The cables or belts are kept tensioned by means of pulleys (24, 25) confined in the slides (23). The distance between the two cloths (1, 2) determines the height of said slides (23). This distance depends on the focal length of the Fresnel lenses (17) used. It is usually situated between 50 mm and 500 mm.

According to a fifth embodiment of the present invention, the linear Fresnel lenses (17) are replaced by concentric Fresnel lenses (26) and the lines of photovoltaic cells (19) placed on the lower cloth (2) are replaced by photovoltaic cells (27) arranged on each focal point of the concentric Fresnel lens (26) (FIG. 6).

According to a sixth embodiment (FIGS. 7, 8 and 9), the first element (1) consists of a set of rigid aluminum bars (28) supported by articulated rods (29) making it possible to move said bars (28) between a retracted position and a deployed position. The second element (2), for its part, is made up of the cloth (2) consisting of a succession of linear parabolic dishes (30), said parabolic dishes (30) being covered with a reflector (31). A shape-memory metal or plastic wire (32) (FIG. 15) is arranged between the reflector (31) and the cloth (2) so that the beam of each parabolic dish (30) has an identical width being situated between 100 mm and 500 mm when the cloth (2) is completely deployed.

Several straps (33) are arranged at regular intervals perpendicularly to the linear parabolic dishes (30) over the whole length of the cloth (2), two of them being arranged on either side of said cloth (2). These straps (33), one of whose ends is fixedly attached to the support (3) and the other of whose ends is fixedly attached to the lambrequin (9), ensure that said parabolic dishes (30) are kept on a single plane. Several polygons (34) are arranged at least at each end of the tube-shaped support (3). When the blind or awning is folded, the linear parabolic dishes (30) are rolled onto the tube (3) while the straps (33) are adjusted on the periphery of the polygons (34). The points of assembly of the strap (33) with the cloth (2) are positioned on one of the apexes of the polygon (34) that is tangential to the surface of the tube (3). This rolling method allows the straps (33) always to be tight when the cloth (2) is rolled onto the support (3).

The lower surface of each bar (28) is covered with a strip of photovoltaic cells (35) on which a row of preferably concentric Fresnel lenses (36) (FIG. 11) is adjusted at approximately 10 mm. Said bars (28) are arranged so as to position the lenses (36) on the focal line of each linear parabolic dish (30). The latter reflects and concentrates the solar radiation, by a factor usually varying between 10 and 20, onto the Fresnel lenses (36). Each lens (36) again concentrates the radiation onto the cells (35). The latter may be, for example made of monocrystalline silicon or be multiple-junction having a surface area of a few mm². A concentration factor of more than 2000 times may be achieved when the multiple-junction cells (35) are used. In this case, the heat given off by the latter is dissipated through the bars (28) the latter being cooled by natural ventilation. In order to increase the coefficient of heat dissipation, the bars (28) are usually tubular.

In a variant of the sixth embodiment, the metal or plastic wire (32) is replaced by a perforated strip (32′). The latter has sufficient rigidity to keep the beam of the parabolic dishes (30) on a single plane without the use of the straps (33).

Unlike the preceding embodiments, the output of the cells (35) inherent in this embodiment is practically unaffected by the movement of the sun on the east-west axis.

According to a seventh embodiment of the present invention, the set of bars (28) is arranged beneath the cloth (1). The latter consists of the flexible and transparent film (16) entirely formed of linear Fresnel lenses (17) as described in the fourth embodiment. The upper surface of said bars (28) comprises cells (37) on which other preferably concentric Fresnel lenses (38) are adjusted.

The blind or awning described according to the various above-mentioned embodiments, usually comprises a system for tilting the cloths (1, 2) on the north-south axis controlled by electric cylinders (not illustrated). Certain embodiments may comprise a reduction gear (39) designed to pivot said cloths (1, 2) on the east-west axis by means of a crown wheel (40) arranged on an axial support (41).

A programmed clock makes it possible to control the reduction gear (39) and/or the cylinders in order to position the cloths (1, 2) at any time of the day perpendicularly to the solar radiation so as to obtain maximum output.

The blind or awning, a simple solar protection intended for patios, pergolas or gardens, therefore becomes a heliostat capable of transforming the maximum of solar energy into electric energy throughout the year.

According to the various embodiments explained above, the present invention has a multitude of advantages:
The surface used by the photovoltaic cells is approximately halved, which substantially reduces the manufacturing cost.
The weight of the blind or awning is thereby considerably reduced.
The electric output is amplified thanks to the optimal exploitation of the direct and diffuse solar rays and the infrared rays originating from the heat of the reflector (7) and the solar cells.

1. A photo-generator blind or awning, characterized in that it comprises a first and a second element (1, 2) in the form of a flexible cloth or of a set of bars (28), the two elements (1, 2) being able to move between a retracted position and a deployed position, the first element (1) being superposed generally parallel on the second element (2) at a certain distance when the latter are deployed, photovoltaic cells (6, 15, 20, 35, 37) being arranged on one and/or other of these elements (1, 2), the active photovoltaic surface of said cells (6, 15, 20, 35, 37) being situated on the upper and/or lower surface of the first element (1) and/or on the upper surface of the second element (2), the first element (1) allowing the sunlight to pass through, at least in part, when the two elements (1, 2) are deployed, the two elements (1, 2) being arranged so that the light is directed onto the active photovoltaic surface of said cells (6, 15, 20, 35, 37) situated on the lower surface of the first element (1) and/or on the upper surface of the second element (2).

2. The photo-generator blind or awning as claimed in claim 1, characterized in that the second element (2) is a cloth comprising a reflector (7) on its upper surface.

3. The photo-generator blind or awning as claimed in claim 2, characterized in that the first element (1) is a cloth, capable of being rolled onto a support (3) said cloth (1) consisting of a transparent film (5) comprising bifacial photovoltaic cells (6), the second element (2) being capable of being rolled up either on the support (3) or on a second support (4).

4. The photo-generator blind or awning as claimed in claim 3, characterized in that said cells (6) are encapsulated in the transparent film (5).

5. The photo-generator blind or awning as claimed in claim 4, characterized in that the spacing between each encapsulated photovoltaic cell (6) is situated between 0.5 and 3 mm.

6. The photo-generator blind or awning as claimed in claim 2, characterized in that the first element (1) is a cloth formed of several tapes (10) made up of thin flexible bifacial films comprising photovoltaic cells, each of said tapes (10) being separated by a band of transparent film (11), the second element (2) reflecting the direct and diffuse solar radiation having passed through said bands (11) on the lower face of the films (10).

7. The photo-generator blind or awning as claimed in claim 6, characterized in that each transparent band (11) is made up of linear Fresnel lenses (14), which concentrate the direct solar radiation onto a line of photovoltaic cells (15) arranged on the reflector (7).

8. The photo-generator blind or awning as claimed in claim 1, characterized in that the first element (1) is a cloth made up of a flexible and transparent film (16) entirely formed of several linear Fresnel lenses (17) designed to concentrate the direct radiation of the sun onto several lines of photovoltaic cells (19) arranged on the upper surface of the second element (2), said second element (2) also being a cloth.

9. The photo-generator blind or awning as claimed in claim 1, characterized in that the element (1) is a cloth made up of a flexible and transparent film (16) comprising concentric Fresnel lenses (26) designed to concentrate the direct radiation of the sun onto several photovoltaic cells (27) arranged on the upper surface of the second element (2), said second element (2) also being a cloth.

10. The photo-generator blind or awning as claimed in claim 1, characterized in that, on the one hand, the first element (1) is made up of a set of bars (28) supported by articulated rods (29), said bars (28) comprising on their lower surface several photovoltaic cells (35) on which Fresnel lenses (36) are adjusted and, on the other hand, the second element (2) is a cloth made up of a succession of linear parabolic dishes (30), the latter being covered by a reflector (31).

11. The photo-generator blind or awning as claimed in claim 10, characterized in that a perforated strip (32′) or a metal or plastic shape-memory wire (32) is arranged between the reflector (31) and the cloth (2) so that each parabolic dish (30) has an identical width when the cloth (2) is completely deployed.

12. The photo-generator blind or awning as claimed in claim 11, characterized in that several straps (33) are arranged at regular intervals perpendicularly to the linear parabolic dishes (30) over the whole length of the blind or awning, one of the ends of each strap (33) being fixedly attached to the support (3), the other of its ends being fixedly attached to a lambrequin (9) in order to keep the beam of each parabolic dish (30) on a single plane.

13. The photo-generator blind or awning as claimed in claim 1, characterized in that the element (1) is a cloth made up of a flexible and transparent film (16) entirely formed of several Fresnel lenses (17) designed to concentrate the direct radiation of the sun onto several photovoltaic cells (37) arranged on the upper surface of the second element (2), said second element (2) being made up of a set of bars (28).

14. The photo-generator blind or awning as claimed in claim 1, characterized in that it comprises a system of tilting the cloths (1, 2) comprising electric cylinders controlled by a clock.

15. The photo-generator blind or awning as claimed in claim 1, characterized in that it comprises a reduction gear (39) designed to pivot said cloths (1, 2) by means of a crown wheel (40) arranged on an axial support (41) fixedly attached to the blind or awning, said reduction gear (39) being controlled by a clock.

16. A photo-generator awning as claimed in claim 1, characterized in that it comprises two slides (23) positioned on each lateral side of the cloths (1, 2), pulleys (24, 25) being arranged in said slides (23) in order to maintain the tension of the cables or the belts fixedly attached to said cloths (1, 2).
